(19) United States
(12) Patent Application Publication
(10) Pub. No.: US 2026/0255821 A1
(43) Pub. Date: Aug. 27, 2026

(54) DISPLAY SUBSTRATE AND DISPLAY PANEL

(71) Applicants: Chongqing BOE Display Technology Co., Ltd., Chongqing (CN); BOE TECHNOLOGY GROUP CO., LTD., Beijing (CN)

(72) Inventors: Xiangyi Li, Beijing (CN); Bo Zhang, Beijing (CN); Yi Qu, Beijing (CN); Haigang Qing, Beijing (CN); Tinghua Shang, Beijing (CN); Rui Wang, Beijing (CN)

(73) Assignees: Chongqing BOE Display Technology Co., Ltd., Chongqing (CN); BOE TECHNOLOGY GROUP CO., LTD., Beijing (CN)

(21) Appl. No.: 19/160,088

(22) PCT Filed: Jul. 15, 2024
(86) PCT No.: PCT/CN2024/105382

§ 371 Date: Aug. 27, 2025

(30) Foreign Application Priority Data
Aug. 25, 2023 (CN) 202311088419.2

(51) Int. Cl. H10K 59/131

(52) U.S. Cl. CPC H10K 59/131

(57) ABSTRACT

A display substrate and a display panel are provided. The display substrate includes: a base substrate; a plurality of first voltage lines and a plurality of second voltage lines arranged on the base substrate and in a first frame region, the second voltage line being arranged between two adjacent first voltage lines in the first direction, the plurality of first voltage lines being electrically coupled to each other, the plurality of second voltage lines being electrically coupled to each other, and a circuit board arranged on the base substrate and in the first frame region, the circuit board being arranged at a side of the first voltage line and the second voltage line away from the display region, and the circuit board being electrically coupled to the plurality of first voltage lines and configured to provide a first voltage signal to the first voltage line.

### CROSS-REFERENCE TO RELATED APPLICATION

This application claims a priority of the Chinese patent application No. 202311088419.2 filed on Aug. 25, 2023, which is incorporated herein by reference in its entirety.

### TECHNICAL FIELD

The present disclosure relates to the field of display technology, in particular to a display substrate and a display panel.

### BACKGROUND

In the related art, in a lower frame region of a display product, few first voltage lines are adopted. In a case of highlighting, a risk of burn occurs due to a large current density of a first voltage signal on the first voltage line.

### SUMMARY

In one aspect, the present disclosure provides in some embodiments a display substrate, including a display region and a first frame region. The display substrate includes: a base substrate; a plurality of first voltage lines and a plurality of second voltage lines arranged on the base substrate and in the first frame region, the second voltage line being arranged between two adjacent first voltage lines in the first direction, the plurality of first voltage lines being electrically coupled to each other, the plurality of second voltage lines being electrically coupled to each other; and a circuit board arranged on the base substrate and in the first frame region, the circuit board being arranged at a side of the first voltage line and the second voltage line away from the display region, and the circuit board being electrically coupled to the plurality of first voltage lines and configured to provide a first voltage signal to the first voltage line

In a possible embodiment of the present disclosure, the display substrate includes at least three second voltage lines arranged in the first frame region, the first voltage line is arranged between the adjacent second voltage lines in the first direction, and the circuit board is electrically coupled to the at least three second voltage lines and configured to provide a second voltage signal to the second voltage line.

In a possible embodiment of the present disclosure, the display substrate includes at least three first voltage lines arranged in the first frame region; and the at least three first voltage lines and the plurality of second voltage lines are arranged sequentially in the first direction.

In a possible embodiment of the present disclosure, the display substrate includes a first one of the first voltage lines, a first one of the second voltage lines, a second one of the first voltage lines, a second one of the second voltage lines and a third one of the first voltage lines arranged sequentially in the first frame region in the first direction; or the display substrate includes a first one of the first voltage lines, a first one of the second voltage lines, a second one of the first voltage lines, a second one of the second voltage lines, a third one of the first voltage lines, a third one of the second voltage lines and a fourth one of the first voltage lines arranged sequentially in the first frame region in the first direction.

In a possible embodiment of the present disclosure, the first frame region includes a bending region and a first region, the first region is arranged at a side of the bending region close to the display region, the display substrate further includes a first metal layer arranged on the base substrate, the display substrate further includes a second voltage communication line formed at the first metal layer, the second voltage communication line extends in the first direction, the second voltage communication line is arranged in the first region, and the plurality of second voltage lines is coupled to the second voltage communication line so that the plurality of second voltage lines is electrically coupled to each other.

In a possible embodiment of the present disclosure, the display substrate further includes a first side region and a second side region, the first region includes an arc-like region, the first side region is arranged at a first side of the display region, the second side region is arranged at a second side of the display region, the first side and the second side are opposite sides, the arc-like region is a region included in the first region close to the first side region or the second side region, and a portion of one of the first voltage lines of the display substrate is arranged in the arc-like region.

In a possible embodiment of the present disclosure, the display substrate further includes a second metal layer arranged at a side of the first metal layer away from the base substrate, the display substrate further includes a plurality of second voltage connection lines arranged in the arc-like region and extending in a second direction, the second voltage connection line is formed at the second metal layer, the first direction intersects the second direction, and the second voltage connection line is electrically coupled to the second voltage communication line via a through-hole.

In a possible embodiment of the present disclosure, the display substrate further includes a first voltage connection line extending in the second direction, and a plurality of first conductive connection members electrically coupled to ends of the first voltage connection lines away from the display region. The first voltage connection line and the first conductive connection member are arranged in the arc-like region, the first direction intersects the second direction, and the first voltage connection line and the first conductive connection member are formed at the second metal layer. The display substrate further includes a first voltage line portion arranged in the arc-like region, the first voltage line portion is included in the first voltage line, the first voltage line portion extends in the first direction and is formed at the first metal layer, an orthogonal projection of the first voltage line portion onto the base substrate at least partially overlaps with an orthogonal projection of the first conductive connection portion onto the base substrate, and the first conductive connection member is electrically coupled to the first voltage line portion via a through-hole.

In a possible embodiment of the present disclosure, the second voltage connection lines and the first conductive connection members are arranged alternately in the first direction.

In a possible embodiment of the present disclosure, the display substrate further includes a plurality of first connection lines and a plurality of second connection lines arranged in the arc-like region, the first connection line and the second connection line extend in a second direction, and the first connection line and the second connection line are formed at a second metal layer; the second connection line is arranged at a side of the first connection line away from the display region, at least two of the first connection lines are electrically coupled to one of the second connection lines, and the first direction intersects the second direction; and the second connection line is electrically coupled to the second voltage communication line via a through-hole.

In a possible embodiment of the present disclosure, the display substrate further includes a plurality of first voltage connection lines arranged in the arc-like region and extending in the second direction, and a plurality of second conductive connection members electrically coupled to ends of the first voltage connection lines away from the display region; the first direction intersects the second direction, and the first voltage connection line and the second conductive connection member are formed at the second metal layer; the display substrate further includes a first voltage line portion arranged in the arc-like region, the first voltage line portion is included in the first voltage line, the first voltage line portion extends in the first direction, the first voltage line portion is formed at the first metal layer, and an orthogonal projection of the first voltage line portion onto the base substrate at least partially overlaps with an orthogonal projection of the second conductive connection member onto the base substrate; and the second conductive connection member is electrically coupled to the first voltage line portion via a through-hole.

In a possible embodiment of the present disclosure, the second connection lines and the second conductive connection members are arranged alternately in the first direction; and an area of the orthogonal projection of the second conductive connection member onto the base substrate is greater than or equal to 500 μm² and smaller than or equal to 1200 μm².

In a possible embodiment of the present disclosure, an orthogonal projection of the second voltage communication line onto the base substrate is arranged at a side of the orthogonal projection of the first voltage line portion onto the base substrate away from the display region.

In a possible embodiment of the present disclosure, in the arc-like region, the first voltage line further includes a second voltage line portion formed at the second metal layer, a third voltage line portion formed at the first metal layer, and a fourth voltage line portion formed at a conductive layer; the second voltage line portion is electrically coupled to the first voltage line portion via a through-hole, and the orthogonal projection of the first voltage line portion onto the base substrate at least partially overlaps with an orthogonal projection of the second voltage line portion onto the base substrate; an orthogonal projection of the third voltage line portion onto the base substrate is arranged at a side of the orthogonal projection of the first voltage line portion onto the base substrate away from the display region; and an orthogonal projection of the fourth voltage line portion onto the base substrate at least partially overlaps with the orthogonal projection of the second voltage line portion onto the base substrate, the orthogonal projection of the fourth voltage line portion onto the base substrate at least partially overlaps with the orthogonal projection of the third voltage line portion onto the base substrate, and the fourth voltage line portion is electrically coupled to the second voltage line portion and the third voltage line portion so that the second voltage line portion is electrically coupled to the third voltage line portion.

In a possible embodiment of the present disclosure, a region included in the first region other than the arc-like region is a middle region, and in the middle region, the first voltage line includes a fifth voltage line portion, a sixth voltage line portion, a seventh voltage line portion, an eighth voltage line portion and a ninth voltage line portion; the fifth voltage line portion, the sixth voltage line portion, the seventh voltage line portion, the eighth voltage line portion and the ninth voltage line portion extend in the first direction; the fifth voltage line portion and the sixth voltage line portion are formed at the first metal layer, the seventh voltage line portion and the eighth voltage line portion are formed at a second metal layer, and the ninth voltage line portion is formed at a conductive layer; an orthogonal projection of the seventh voltage line portion onto the base substrate and an orthogonal projection of the ninth voltage line portion onto the base substrate at least partially overlap with an orthogonal projection of the second voltage communication line onto the base substrate; the ninth voltage line portion, the seventh voltage line portion, the fifth voltage line portion and the sixth voltage line portion are electrically coupled to each other; and the seventh voltage line portion is electrically coupled to the eighth voltage line portion.

In a possible embodiment of the present disclosure, a length of the second voltage communication line in a second direction is greater than or equal to 20 μm and smaller than or equal to 120 μm.

In a possible embodiment of the present disclosure, the seventh voltage line portion is electrically coupled to the eighth voltage line portion via a through-hole, the seventh voltage line portion is in direct contact with the eighth voltage line portion at the through-hole, and an area of the seventh voltage line portion in direct contact with the eighth voltage line portion is greater than or equal to 40000 μm² and smaller than or equal to 100000 μm².

In another aspect, the present disclosure provides in some embodiments a display panel including the above-mentioned display substrate.

### BRIEF DESCRIPTION OF THE DRAWINGS

FIG. 1 is a schematic view showing the layout of a first frame region of a display substrate according to at least one embodiment of the present disclosure;

FIG. 2A is a schematic view showing the layout of a left half portion of the first frame region in FIG. 1A;

FIG. 2B is a schematic view showing the layout of a first gate metal layer in FIG. 2A;

FIG. 2C is a schematic view showing the layout of a second gate metal layer in FIG. 2B;

FIG. 2D is a schematic view showing the layout of a first source/drain metal layer in FIG. 2A;

FIG. 2E is a schematic view showing the layout of a second source/drain metal layer in FIG. 2A;

FIG. 2F is a schematic view showing the layout of an anode layer in FIG. 2B;

FIG. 3 is a schematic view showing the layout of the first frame region of the display substrate according to at least one embodiment of the present disclosure;

FIG. 4A is a schematic view showing the layout of the first frame region of the display substrate according to at least one embodiment of the present disclosure;

FIG. 4B is a schematic view showing the layout of the first frame region of the display substrate according to at least one embodiment of the present disclosure;

FIG. 5 is a schematic view showing the first frame region in FIG. 4A added with a first dotted box X1 and a second dotted box X2;

FIG. 6 is a schematic view showing the layout of a portion of the first frame region in the first dotted box X1 in FIG. 5;

FIG. 7 is a schematic view showing the layout of the first source/drain metal layer in FIG. 6;

FIG. 8 is a schematic view showing the layout of the second source/drain metal layer in FIG. 6;

FIG. 9 is a schematic view showing the layout of the anode layer in FIG. 6;

FIG. 10 is a schematic view showing the layout of a third region Q3 in FIG. 6;

FIG. 11 is a sectional view of the third region in FIG. 10 along line A-A′;

FIG. 12 is a sectional view of the third region in FIG. 10 along line B-B′;

FIG. 13 is a schematic view showing the layout of the third region in a first arc-like region of the display substrate according to one embodiment of the present disclosure;

FIG. 14 is a schematic view showing the layout of the first source/drain metal layer in FIG. 13;

FIG. 15 is a schematic view showing the layout of the second source/drain metal layer in FIG. 13;

FIG. 16 is a schematic view showing the layout of the anode layer in FIG. 13;

FIG. 17 is a schematic view showing the layout of a portion of the first frame region in the second dotted box X2 in FIG. 5;

FIG. 18 is a schematic view showing the layout of the first source/drain metal layer in FIG. 17:

FIG. 19 is a schematic view showing the layout of the second source/drain metal layer in FIG. 17;

FIG. 20 is a schematic view showing the layout of the anode layer in FIG. 17;

FIG. 21 is a sectional view of the first frame region in FIG. 17 along line C-C′;

FIG. 22 is a sectional view of the first frame region in FIG. 17 along line D-D′; and

FIG. 23 is a schematic view showing the layout of the first frame region of the display substrate according to at least one embodiment of the present disclosure.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

All transistors adopted in the embodiments of the present disclosure may be thin film transistors, field effect transistors or any other elements having an identical characteristic. In order to differentiate two electrodes other than a gate electrode from each other, one of the two electrodes is called as first electrode and the other is called as second electrode.

In actual use, when the transistor is a thin film transistor or field effect transistor, the first electrode may be a drain electrode and the second electrode may be a source electrode, or the first electrode may be a source electrode and the second electrode may be a drain electrode.

The present disclosure provides in some embodiments a display substrate, which includes a display region and a first frame region. The display substrate includes: a base substrate; a plurality of first voltage lines and a plurality of second voltage lines arranged on the base substrate and in the first frame region, the second voltage line being arranged between two adjacent first voltage lines in the first direction, the plurality of first voltage lines being electrically coupled to each other, the plurality of second voltage lines being electrically coupled to each other; and a circuit board arranged on the base substrate and in the first frame region, the circuit board being arranged at a side of the first voltage line and the second voltage line away from the display region, and the circuit board being electrically coupled to the plurality of first voltage lines and configured to provide a first voltage signal to the first voltage line.

In a possible embodiment of the present disclosure, the first direction is a horizontal direction.

In at least one embodiment of the present disclosure, the display substrate includes the base substrate, the plurality of first voltage lines, the plurality of second voltage lines and the circuit board.

In a display product using a VSS In Panel (SIP) technology, in order to reduce a current density of the first voltage lines (i.e., low voltage lines) at a left side and a right side, reduce an IR drop on the first voltage line and improve the brightness uniformity, in the embodiments of the present disclosure, the first voltage line is added in the first frame region of the display substrate. To be specific, the plurality of first voltage lines is arranged in the first frame region and electrically coupled to each other, and the plurality of first voltage lines is electrically coupled to the circuit board to receive the first voltage signal provided by the circuit board, so as to shunt the first voltage signal, and prevent the occurrence of a risk of burn due to a large current density of the first voltage signal on the first voltage lines at the left side and the right side in case of highlighting.

During the implementation, the display substrate further includes a gate line arranged in the display region, and the gate line extends in the horizontal direction.

In a possible embodiment of the present disclosure, the added first voltage line is arranged in a middle region of the first frame region.

In the first frame region, at least one of the second voltage lines is arranged between two adjacent first voltage lines.

In at least one embodiment of the present disclosure, the display substrate includes at least three second voltage lines arranged in the first frame region, the first voltage line is arranged between the adjacent second voltage lines in the first direction, and the circuit board is electrically coupled to the at least three second voltage lines and configured to provide a second voltage signal to the second voltage line.

During the implementation, the second voltage line is added at a central position of the first frame region, and the first voltage line is newly added at either of the left side and the right side of the second voltage line. In at least one embodiment of the present disclosure, the newly-added first voltage lines and the second voltage line are electrically coupled to the circuit board, so as to shunt the first voltage signal and the second voltage signal simultaneously, and reduce a load of the first voltage line and a load of the second voltage line, thereby to improve the display brightness uniformity.

In a possible embodiment of the present disclosure, the display substrate includes at least three first voltage lines arranged in the first frame region; and the at least three first voltage lines and the plurality of second voltage lines are arranged sequentially in the first direction.

During the implementation, the display substrate includes the at least three first voltage lines arranged in the first frame region, and the at least three first voltage lines and the plurality of second voltage lines are arranged sequentially in the first direction.

In at least one embodiment of the present disclosure, the display substrate includes a first one of the first voltage lines, a first one of the second voltage lines, a second one of the first voltage lines, a second one of the second voltage lines and a third one of the first voltage lines arranged sequentially in the first frame region in the first direction; or the display substrate includes a first one of the first voltage lines, a first one of the second voltage lines, a second one of the first voltage lines, a second one of the second voltage lines, a third one of the first voltage lines, a third one of the second voltage lines and a fourth one of the first voltage lines arranged sequentially in the first frame region in the first direction.

During the implementation, in the first frame region, the display substrate includes the first one of the first voltage lines, the first one of the second voltage lines, the second one of the first voltage lines, the second one of the second voltage lines and the third one of the first voltage lines arranged sequentially in the horizontal direction. The first one of the first voltage lines, the second one of the first voltage lines and the third one of the first voltage lines are electrically coupled to each other, and the first one of the second voltage lines and the second one of the second voltage lines are electrically coupled to each other. The first one of the first voltage lines, the first one of the second voltage lines, the second one of the first voltage lines, the second one of the second voltage lines and the third one of the first voltage lines are electrically coupled to the circuit board, and configured to receive the voltage signals provided by the circuit board.

The second one of the first voltage lines in the middle is electrically coupled to the circuit board via two ports, so as to receive the first voltage signal provided by the circuit board, thereby to further shunt the first voltage signal.

During the implementation, in the first frame region, the display substrate includes the first one of the first voltage lines, the first one of the second voltage lines, the second one of the first voltage lines, the second one of the second voltage lines, the third one of the first voltage lines, the third one of the second voltage lines and the fourth one of the first voltage lines arranged sequentially in the first direction. The first one the first voltage lines, the second one of the first voltage lines, the third one of the first voltage lines and the fourth one of the first voltage lines are electrically coupled to each other, and the first one of the second voltage lines, the second one of the second voltage lines and the third one of the second voltage lines are electrically coupled to each other. the first one of the first voltage lines, the first one of the second voltage lines, the second one of the first voltage lines, the second one of the second voltage lines, the third one of the first voltage lines, the third one of the second voltage lines and the fourth one of the first voltage lines are electrically coupled to the circuit board, and configured to receive the voltage signals provided by the circuit board.

The second one of the second voltage lines in the middle of the first frame region is electrically coupled to the circuit board via two ports, so as to receive the second voltage signal provided by the circuit board, thereby to further shunt the second voltage signal.

In at least one embodiment of the present disclosure, the first frame region is a lower frame region.

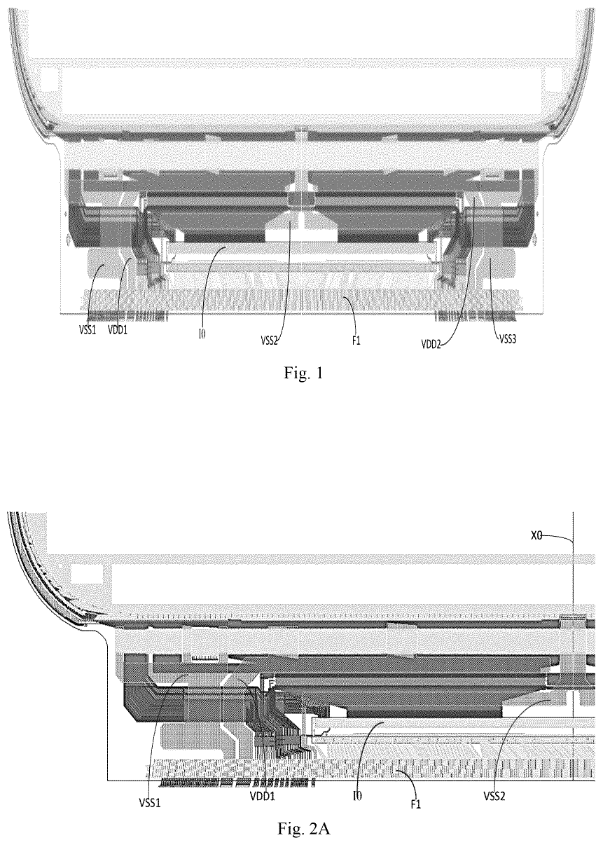

FIG. 1 is a schematic view showing the layout of the first frame region of the display substrate according to at least one embodiment of the present disclosure.

In FIG. 1, VSS1 represents the first one of the first voltage lines, VDD1 represents the first one of the second voltage lines, VSS2 represents the second one of the first voltage lines, VDD2 represents the second one of the second voltage lines, VSS3 represents the third one of the first voltage lines, I0 represents a driving integrated circuit, and F1 represents a flexible printed circuit for providing the first voltage signal and the second voltage signal.

In at least one embodiment of the present disclosure, the first voltage line is, but not limited to, a low voltage line, and the second voltage line is, but not limited to, a high voltage line.

VSS1, VSS2 and VSS3 are electrically coupled to different ports of the flexible printed circuit F1, and configured to receive the first voltage signal provided by the flexible printed circuit F1. VDD1 and VDD2 are electrically coupled to different ports of the flexible printed circuit F1, and configured to receive the second voltage signal provided by the flexible printed circuit F1.

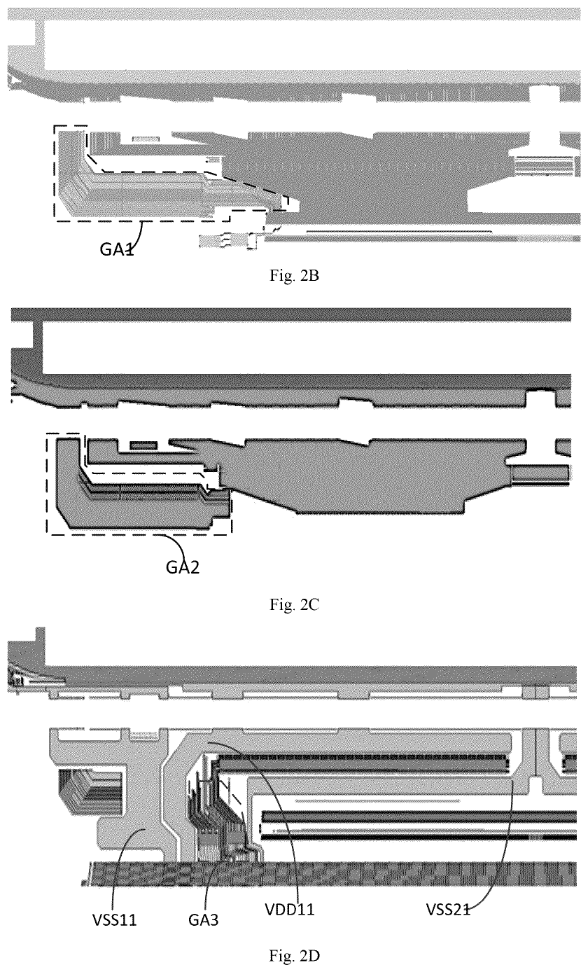

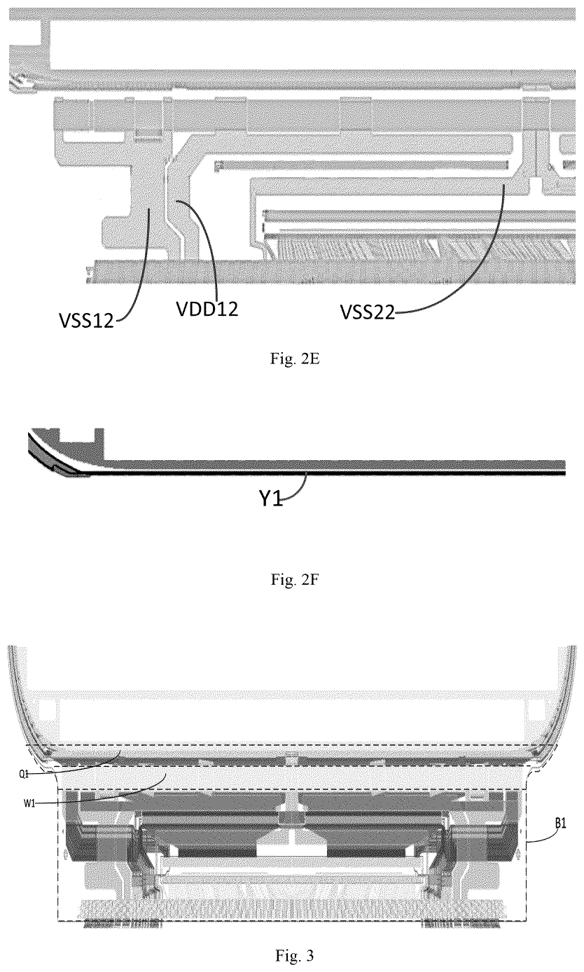

FIG. 2A is a schematic view showing the layout of a left half portion of the first frame region in FIG. 1, where X0 represents a central line of the lower frame region of the display substrate.

FIG. 2B is a schematic view showing the layout of a first gate metal layer in FIG. 2A, FIG. 2C is a schematic view showing the layout of a second gate metal layer in FIG. 2B, FIG. 2D is a schematic view showing the layout of a first source/drain metal layer in FIG. 2A. FIG. 2E is a schematic view showing the layout of a second source/drain metal layer in FIG. 2A, and FIG. 2F is a schematic view showing the layout of an anode layer in FIG. 2B.

In FIG. 2B, GA1 represents a first Gate On Array (GOA) signal line region, and a GOA signal line is arranged in GA1.

In FIG. 2C, GA2 represents a second GOA signal line region, and a GOA signal line is arranged in GA2.

In FIG. 2D, GA3 represents a third GOA signal line region, and a GOA signal line is arranged in GA3.

In FIG. 2D, VSS11 represents a first signal line portion included in VSS1, VDD11 represents a first signal line portion included in VDD1, and VSS21 represents a first signal line portion included in VSS2.

In FIG. 2E, VSS12 represents a second signal line portion included in VSS1, VDD12 represents a second signal line portion included in VDD1, and VSS22 represents a second signal line portion included in VSS2.

In FIG. 2F, Y1 represents an anode pattern.

In at least one embodiment of the present disclosure, the first frame region includes a bending region and a first region, the first region is arranged at a side of the bending region close to the display region, the display substrate further includes a first metal layer arranged on the base substrate, the display substrate further includes a second voltage communication line formed at the first metal layer, the second voltage communication line extends in the first direction, the second voltage communication line is arranged in the first region, and the plurality of second voltage lines is coupled to the second voltage communication line so that the plurality of second voltage lines is electrically coupled to each other.

In FIG. 3, Q1 represents the first region, W1 represents the bending region, and B1 represents the first frame region.

In a possible embodiment of the present disclosure, the display substrate further includes a first side region and a second side region, the first region includes an arc-like region, the first side region is arranged at a first side of the display region, the second side region is arranged at a second side of the display region, the first side and the second side are opposite sides, the arc-like region is a region included in the first region close to the first side region or the second side region, and a portion of one of the first voltage lines of the display substrate is arranged in the arc-like region.

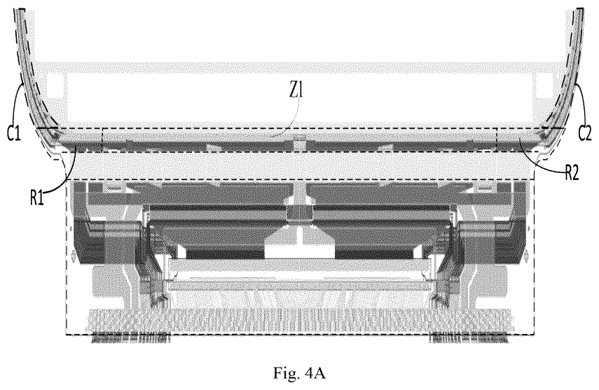

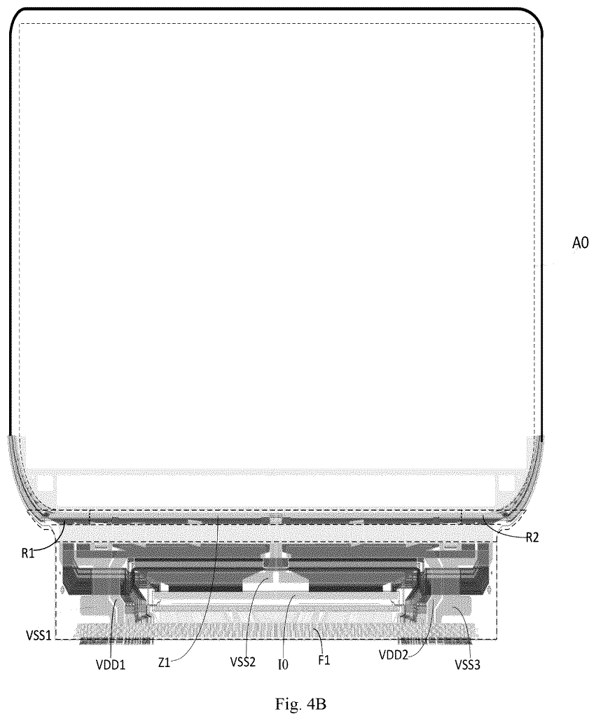

In FIG. 4A, C1 represents the first side region, C2 represents the second side region, R1 represents a first arc-like region, and R2 represents a second arc-like region.

In FIG. 4A, a portion of a first one of the first voltage lines V1 is arranged in the first arc-like region R1.

In at least one embodiment of the present disclosure, the first side region is a region arranged at a left side of the display region, the second side region is a region arranged at a right side of the display region, and a GOA circuit is arranged in the first side region and/or the second side region.

In FIG. 4B, A0 represents the display region.

In at least one embodiment of the present disclosure, the display substrate further includes a second metal layer arranged at a side of the first metal layer away from the base substrate, the display substrate further includes a plurality of second voltage connection lines arranged in the arc-like region and extending in a second direction, the second voltage connection line is formed at the second metal layer, the first direction intersects the second direction, and the second voltage connection line is electrically coupled to the second voltage communication line via a through-hole.

In a possible embodiment of the present disclosure, the first metal layer is a first source/drain metal layer, the second metal layer is a second source/drain metal layer, and the conductive layer is an anode layer.

In at least one embodiment of the present disclosure, the first direction is, but not limited to, a horizontal direction, and the second direction is, but not limited to, a vertical direction.

FIG. 5 is a schematic view showing the first frame region in FIG. 4A added with a first dotted box X1 and a second dotted box X2.

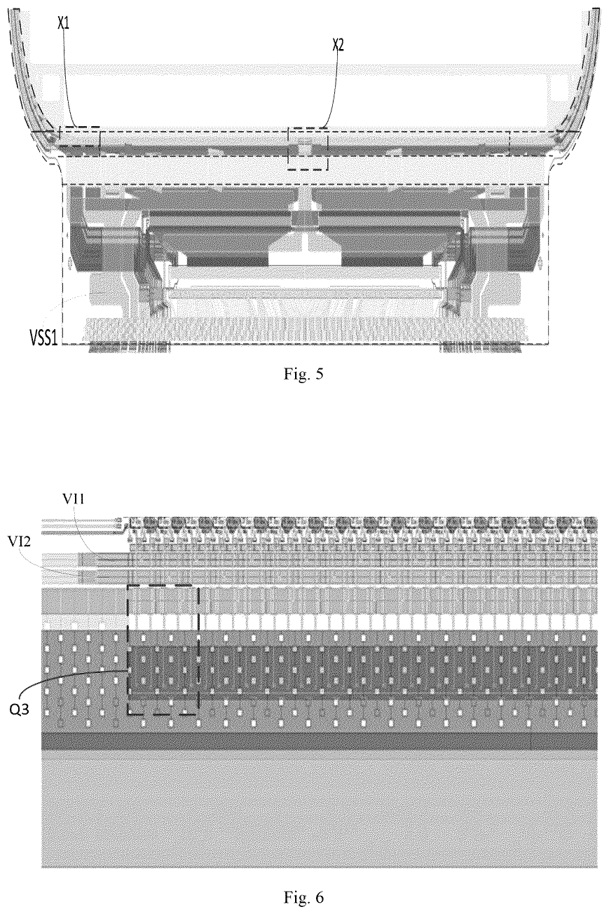

FIG. 6 is a schematic view showing the layout of a portion of the first frame region in the first dotted box X1 in FIG. 5.

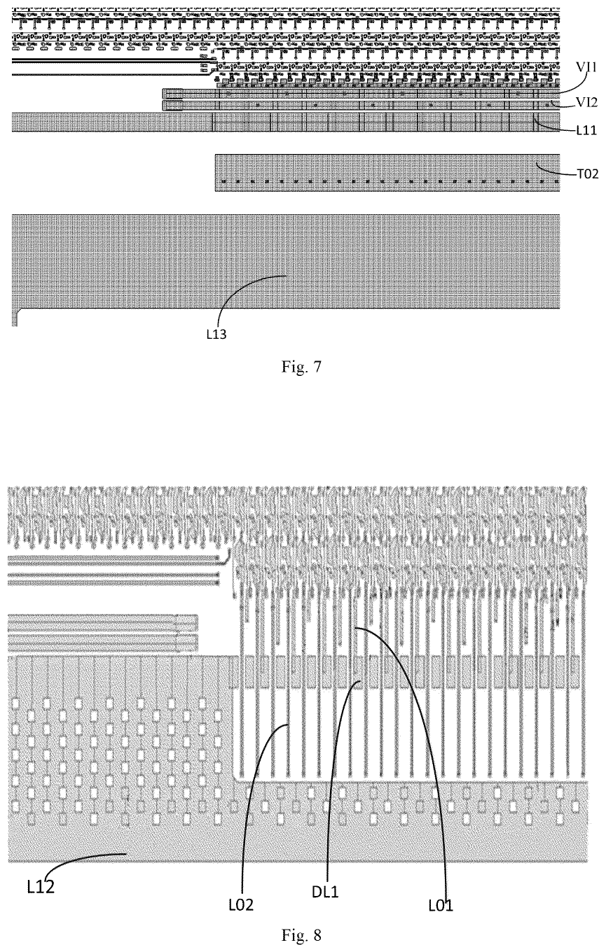

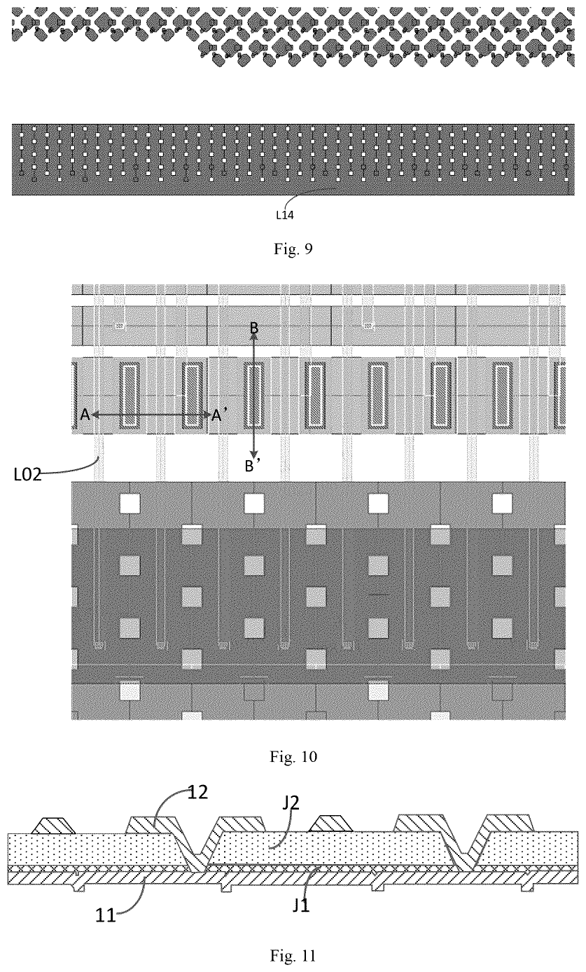

FIG. 7 is a schematic view showing the layout of the first source/drain metal layer in FIG. 6, FIG. 8 is a schematic view showing the layout of the second source/drain metal layer in FIG. 6, and FIG. 9 is a schematic view showing the layout of the anode layer in FIG. 6.

In FIG. 8, L02 represents the second voltage connection line, and the second voltage connection line L02 extends in the vertical direction and is formed at the second source/drain metal layer. In FIG. 7, T02 represents the second voltage communication line, and the second voltage communication line T02 is formed at the first source/drain metal layer and extends in the horizontal direction. The second voltage connection line L02 is electrically coupled to the second voltage communication line T02 via a through-hole.

In at least one embodiment of the present disclosure, the display substrate further includes a first voltage connection line extending in the second direction, and a plurality of first conductive connection members electrically coupled to ends of the first voltage connection lines away from the display region. The first voltage connection line and the first conductive connection member are arranged in the arc-like region, the first direction intersects the second direction, and the first voltage connection line and the first conductive connection member are formed at the second metal layer. The display substrate further includes a first voltage line portion arranged in the arc-like region, the first voltage line portion is included in the first voltage line, the first voltage line portion extends in the first direction and is formed at the first metal layer, an orthogonal projection of the first voltage line portion onto the base substrate at least partially overlaps with an orthogonal projection of the first conductive connection portion onto the base substrate, and the first conductive connection member is electrically coupled to the first voltage line portion via a through-hole.

As shown in FIG. 8, L01 represents the first voltage connection line, and DL1 represents the first conductive connection member. The first voltage connection line L01 extends in the vertical direction, the first conductive connection member DL1 is electrically coupled to an end of the first voltage connection line L01 away from the display region, and L01 and DL1 are both formed at the second source/drain metal layer.

As shown in FIG. 7, L11 represents the first voltage line portion, and the first voltage line portion L11 extends in the horizontal direction.

As shown in FIGS. 6 to 9, the orthogonal projection of the first voltage line portion L11 onto the base substrate at least partially overlaps with the orthogonal projection of the first conductive connection member DL1 onto the base substrate, and L11 is electrically coupled to DL1 via a through-hole.

In a possible embodiment of the present disclosure, the second voltage connection lines and the first conductive connection members are arranged alternately in the first direction.

As shown in FIG. 8, the second voltage connection lines L02 and the first conductive connection members DL1 are arranged alternately in the horizontal direction.

In at least one embodiment of the present disclosure, the orthogonal projection of the second voltage communication line onto the base substrate is arranged at a side of the orthogonal projection of the first voltage line portion onto the base substrate away from the display region.

As shown in FIGS. 6 to 9, the orthogonal projection of the second voltage communication line T02 onto the base substrate is arranged at a side of the orthogonal projection of the first voltage line portion L11 onto the base substrate away from the display region.

In at least one embodiment of the present disclosure, the first voltage lines are electrically coupled to each other via the voltage line portion arranged at the anode layer.

In at least one embodiment of the present disclosure, in the arc-like region, the first voltage line further includes a second voltage line portion formed at the second metal layer, a third voltage line portion formed at the first metal layer, and a fourth voltage line portion formed at a conductive layer. The second voltage line portion is electrically coupled to the first voltage line portion via a through-hole, and the orthogonal projection of the first voltage line portion onto the base substrate at least partially overlaps with an orthogonal projection of the second voltage line portion onto the base substrate. An orthogonal projection of the third voltage line portion onto the base substrate is arranged at a side of the orthogonal projection of the first voltage line portion onto the base substrate away from the display region. An orthogonal projection of the fourth voltage line portion onto the base substrate at least partially overlaps with the orthogonal projection of the second voltage line portion onto the base substrate, the orthogonal projection of the fourth voltage line portion onto the base substrate at least partially overlaps with the orthogonal projection of the third voltage line portion onto the base substrate, and the fourth voltage line portion is electrically coupled to the second voltage line portion and the third voltage line portion so that the second voltage line portion is electrically coupled to the third voltage line portion.

As shown in FIGS. 6 to 9, in the first arc-like region, the first voltage line further includes a second voltage line portion L12 formed at the second source/drain metal layer, a third voltage line portion L13 formed at the first source/drain metal layer, and a fourth voltage line portion L14 formed at the conductive layer. The second voltage line portion L12 is electrically coupled to the first voltage line L11 via a through-hole, and an orthogonal projection of the first voltage line portion L11 onto the base substrate at least partially overlaps with an orthogonal projection of the second voltage line portion L12 onto the base substrate. An orthogonal projection of the third voltage line portion L13 onto the base substrate is arranged at a side of the orthogonal projection of the first voltage line portion L11 onto the base substrate. An orthogonal projection of the fourth voltage line portion L14 onto the base substrate at least partially overlaps with the orthogonal projection of the second voltage line portion L12 onto the base substrate, the orthogonal projection of the fourth voltage line portion L14 onto the base substrate at least partially overlaps with the orthogonal projection of the third voltage line portion L13 onto the base substrate, and the fourth voltage line portion L14 is electrically coupled to the second voltage line portion L12 and the third voltage line portion L13 so that the second voltage line portion L12 is electrically coupled to the third voltage line portion L13.

FIG. 10 is a schematic view showing the layout of a third region Q3 in FIG. 6.

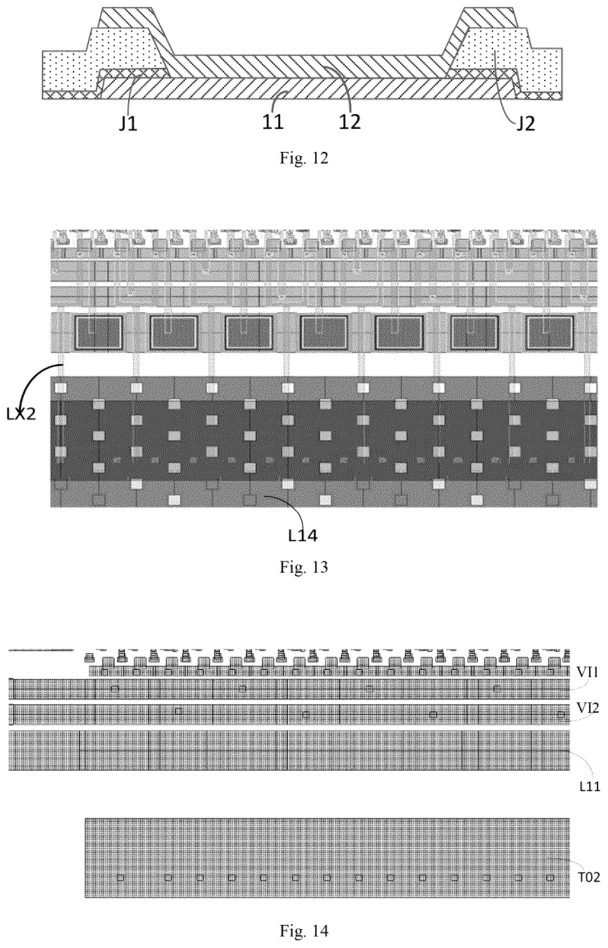

FIG. 11 is a sectional view of the third region in FIG. 10 along line A-A′, and FIG. 12 is a sectional view of the third region in FIG. 10 along line B-B′.

In FIGS. 11 and 12, 11 represents the first source/drain metal layer, 12 represents the second source/drain metal layer, JI represents a first insulation layer, and J2 represents a second insulation layer.

In a possible embodiment of the present disclosure, the first insulation layer J1 is a passivation layer, and the second insulation layer J2 is a planarization layer.

In FIG. 7, VI1 represents a first initial voltage line, VI2 represents a second initial voltage line, and VI1 and VI2 extend in the horizontal direction.

As shown in FIGS. 6 to 9, the second voltage connection line L02 spans over the first initial voltage line V, the second initial voltage line VI2 and the first voltage line portion L11 to be electrically coupled to the second voltage communication line T02. The first voltage connection line L01 spans over the first initial voltage line VI1 and the second initial voltage line VI2 to be electrically coupled to the first conductive connection member DL1, and DL1 formed at the second source/drain metal layer is electrically coupled to the first voltage line portion L11 formed at the first source/drain metal layer via a through-hole.

In at least one embodiment of the present disclosure, the first voltage line is lapped onto the second voltage line in the lower frame region through a dual-SD layer process, so one mask is saved.

In at least one embodiment of the present disclosure, the display substrate further includes a plurality of first connection lines and a plurality of second connection lines arranged in the arc-like region, the first connection line and the second connection line extend in a second direction, and the first connection line and the second connection line are formed at a second metal layer; the second connection line is arranged at a side of the first connection line away from the display region, at least two of the first connection lines are electrically coupled to one of the second connection lines, and the first direction intersects the second direction; and the second connection line is electrically coupled to the second voltage communication line via a through-hole.

During the implementation, the display substrate includes the plurality of first connection lines and second connection lines arranged in the arc-like region and extending in the vertical direction, the first connection line and the second connection line are both formed at the second source/drain metal layer, the first connection line is arranged below the first connection line, at least two first connection lines are electrically coupled to one of the second connection lines, and the second connection line is electrically coupled to the second voltage communication line via a through-hole.

In actual use, the first connection line is electrically coupled to a signal line arranged in the display region for transmitting the second voltage signal.

In at least one embodiment of the present disclosure, the display substrate further includes a plurality of first voltage connection lines arranged in the arc-like region and extending in the second direction, and a plurality of second conductive connection members electrically coupled to ends of the first voltage connection lines away from the display region. The first direction intersects the second direction, and the first voltage connection line and the second conductive connection member are formed at the second metal layer. The display substrate further includes a first voltage line portion arranged in the arc-like region, the first voltage line portion is included in the first voltage line, the first voltage line portion extends in the first direction, the first voltage line portion is formed at the first metal layer, and an orthogonal projection of the first voltage line portion onto the base substrate at least partially overlaps with an orthogonal projection of the second conductive connection member onto the base substrate. The second conductive connection member is electrically coupled to the first voltage line portion via a through-hole.

In a possible embodiment of the present disclosure, the second connection lines and the second conductive connection members are arranged alternately in the first direction; and an area of the orthogonal projection of the second conductive connection member onto the base substrate is greater than or equal to 500 μm² and smaller than or equal to 1200 μm². For example, the area of the orthogonal projection of the second conductive connection member onto the base substrate is 800 μm².

FIG. 13 is a schematic view showing the layout of the third region in the first are-like region of the display substrate.

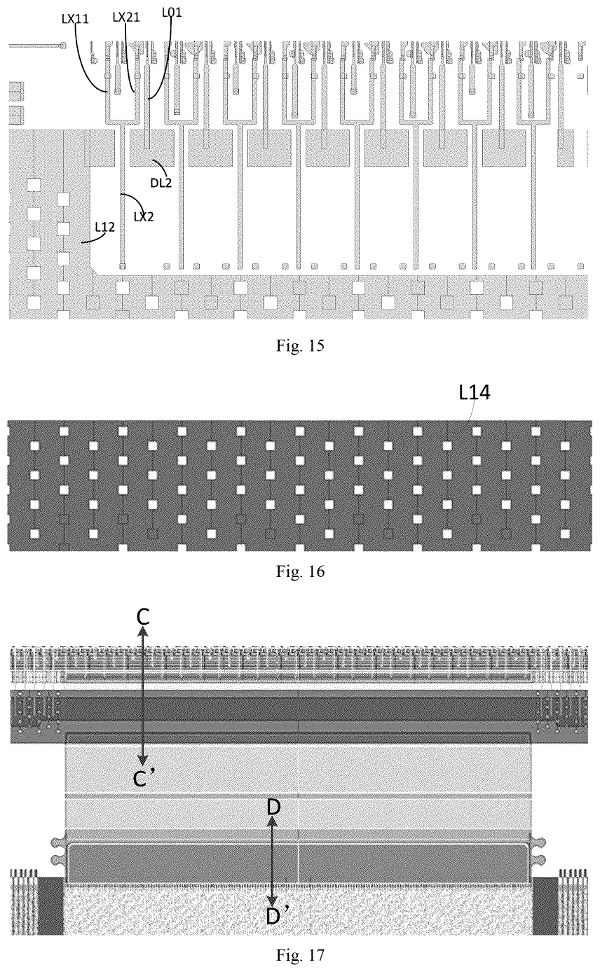

FIG. 14 is a schematic view showing the layout of the first source/drain metal layer in FIG. 13, FIG. 15 is a schematic view showing the layout of the second source/drain metal layer in FIG. 13, and FIG. 16 is a schematic view showing the layout of the anode layer in FIG. 13.

In FIG. 15, LX11 represents a first one of the first connection lines, LX21 represents a second one of the first connection lines, and LX2 represents the second connection line. LX11, LX21 and LX2 extend in the vertical direction, LX2 is arranged at a side of LX11 and LX21 away from the display region, LX11 is electrically coupled to LX21, and LX2 is electrically coupled to LX11 and LX21.

In FIG. 14, T02 represents the second voltage communication line, and as shown in FIGS. 13 to 16, LX2 is electrically coupled to T02 via a through-hole.

In FIG. 14, VI1 represents the first initial voltage line, VI2 represents the second initial voltage line, and VI1, VI2 and T02 all extend in the horizontal direction.

As shown in FIG. 15, L01 represents the first voltage connection line, DL2 represents the second conductive connection member, and L12 represents the second voltage line portion. DL2 is electrically coupled to an end of L01 away from the display region, and L01 and DL2 are both formed at the second source/drain metal layer.

As shown in FIG. 14, L11 represents the first voltage line portion, the first voltage line portion L11 extends in the horizontal direction, the orthogonal projection of the first voltage line portion L11 onto the base substrate at least partially overlaps with the orthogonal projection of the second conductive connection member DL2 onto the base substrate, and the second conductive connection member DL2 is electrically coupled to the first voltage line portion L11.

As shown in FIG. 15, an area of the orthogonal projection of the second conductive connection member DL2 onto the base substrate is greater than or equal to 500 μm² and smaller than or equal to 1200 μm², so as to increase an aperture area for the lapping of a segment of the first voltage line.

In FIG. 16, L14 represents the fourth voltage line portion.

As shown in FIGS. 13 to 16, the second voltage line portion L12 is electrically coupled to the first voltage line portion L11 via a through-hole, and the orthogonal projection of the first voltage line portion L11 onto the base substrate at least partially overlaps with the orthogonal projection of the second voltage line portion L12 onto the base substrate. The orthogonal projection of the fourth voltage line portion L14 onto the base substrate at least partially overlaps with the orthogonal projection of the second voltage line portion L12 onto the base substrate, and the fourth voltage line portion L14 is electrically coupled to the second voltage line portion L12.

In at least one embodiment of the present disclosure, as shown in FIGS. 13 to 16, it is able to reduce an overlapping area between the connection line for transmitting the second voltage signal and the first voltage line portion L11.

In at least one embodiment of the present disclosure, a region included in the first region other than the arc-like region is a middle region, and in the middle region, the first voltage line includes a fifth voltage line portion, a sixth voltage line portion, a seventh voltage line portion, an eighth voltage line portion and a ninth voltage line portion; the fifth voltage line portion, the sixth voltage line portion, the seventh voltage line portion, the eighth voltage line portion and the ninth voltage line portion extend in the first direction; the fifth voltage line portion and the sixth voltage line portion are formed at the first metal layer, the seventh voltage line portion and the eighth voltage line portion are formed at a second metal layer, and the ninth voltage line portion is formed at a conductive layer; an orthogonal projection of the seventh voltage line portion onto the base substrate and an orthogonal projection of the ninth voltage line portion onto the base substrate at least partially overlap with an orthogonal projection of the second voltage communication line onto the base substrate; the ninth voltage line portion, the seventh voltage line portion, the fifth voltage line portion and the sixth voltage line portion are electrically coupled to each other; and the seventh voltage line portion is electrically coupled to the eighth voltage line portion.

In at least one embodiment of the present disclosure, through two source/drain metal layers, the first voltage line is lapped onto the second voltage line, so as to reduce the quantity of masks.

In a possible embodiment of the present disclosure, a length of the second voltage communication line in the second direction is greater than or equal to 20 μm and smaller than or equal to 120 μm. For example, the length of the second voltage communication line in the second direction is 80 μm.

During the implementation, a line width of the second voltage communication line is reduced, so as to reduce an overlapping area between the first voltage line and the second voltage line.

In at least one embodiment of the present disclosure, the seventh voltage line portion is electrically coupled to the eighth voltage line portion via a through-hole, the seventh voltage line portion is in direct contact with the eighth voltage line portion at the through-hole, and an area of the seventh voltage line portion in direct contact with the eighth voltage line portion is greater than or equal to 40000 μm² and smaller than or equal to 100000 μm². For example, the area of the seventh voltage line portion in direct contact with the eighth voltage line portion is 52500 μm².

During the implementation, at the through-hole, the area of the seventh voltage line portion in direct contact with the eighth voltage line portion is relatively large, so as to increase an overlapping area between the first source/drain metal layer and the second source/drain metal layer as possible while avoiding an organic clearance area inside and outside a DAM.

FIG. 17 is a schematic view showing the layout of a portion of the first frame region in the second dotted box X2 in FIG. 5.

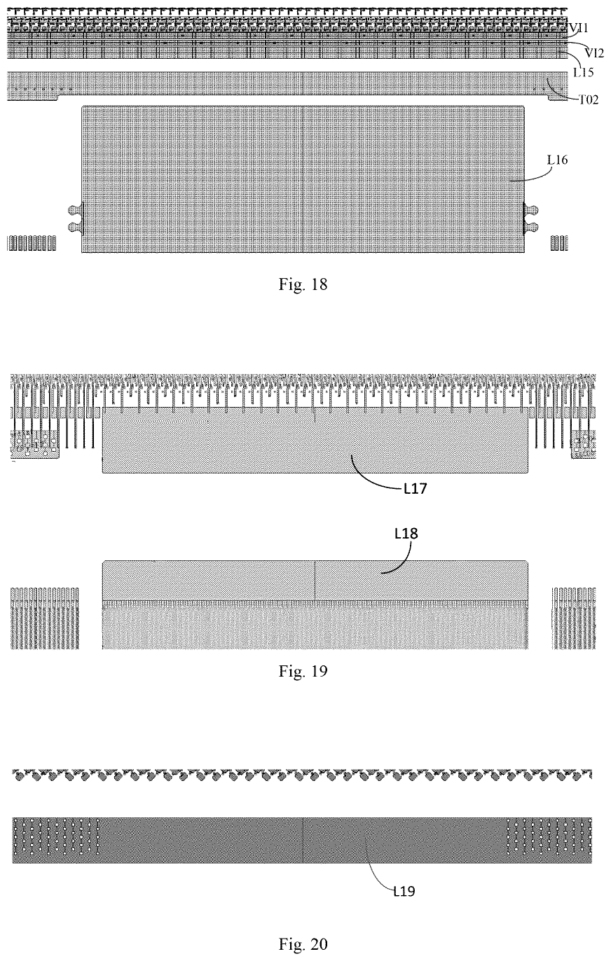

FIG. 18 is a schematic view showing the layout of the first source/drain metal layer in FIG. 17, FIG. 19 is a schematic view showing the layout of the second source/drain metal layer in FIG. 17, and FIG. 20 is a schematic view showing the layout of the anode layer in FIG. 17.

In at least one embodiment of the present disclosure, a region included in the first region other than the arc-like region is a middle region, and in FIG. 4, Z1 represents the middle region.

As shown in FIGS. 17 to 20, the middle region, the first voltage line includes a fifth voltage line portion L15, a sixth voltage line portion L16, a seventh voltage line portion L17, an eighth voltage line portion L18 and a ninth voltage line portion L19.

The fifth voltage line portion L15, the sixth voltage line portion L16, the seventh voltage line portion L17, the eighth voltage line portion L18 and the ninth voltage line portion L19 extend in the first direction.

The fifth voltage line portion L15 and the sixth voltage line portion L16 are formed at the first metal layer, the seventh voltage line portion L17 and the eighth voltage line portion L18 are formed at a second metal layer, and the ninth voltage line portion L19 is formed at a conductive layer.

An orthogonal projection of the seventh voltage line portion L17 onto the base substrate and an orthogonal projection of the ninth voltage line portion L19 onto the base substrate at least partially overlap with an orthogonal projection of the second voltage communication line T02 onto the base substrate.

The ninth voltage line portion L19, the seventh voltage line portion L17, the fifth voltage line portion L15 and the sixth voltage line portion L16 are electrically coupled to each other; and the seventh voltage line portion L17 is electrically coupled to the eighth voltage line portion L18.

In FIG. 18, L15 represents the fifth voltage line portion, L16 represents the sixth voltage line portion, VI1 represents the first initial voltage line, VI2 represents the second initial voltage line, and T02 represents the second voltage communication line. L15, L16, VI1, VI2 and T02 extend in the horizontal direction.

In FIG. 19, L17 represents the seventh voltage line portion, and L18 represents the eighth voltage line portion. In FIG. 20, L19 represents the ninth voltage line portion.

As shown in FIG. 18, a length of the second voltage communication line T02 in the vertical direction is 80 μm.

During the implementation, a line width of the second voltage communication line T02 is reduced, so as to reduce an overlapping area between the first voltage line and the second voltage line.

As shown in FIGS. 17 to 20, the seventh voltage line portion L17 is electrically coupled to the eighth voltage line portion L18 via a through-hole. At the through-hole, the seventh voltage line portion L17 is in direct contact with the eighth voltage line portion L18, and an area of the seventh voltage line portion L17 in direct contact with the eighth voltage line portion L18 is 52500 μm².

During the implementation, at the through-hole, the area of the seventh voltage line portion in direct contact with the eighth voltage line portion is relatively large, so as to increase an overlapping area between the first source/drain metal layer and the second source/drain metal layer as possible while avoiding the organic clearance area inside and outside the DAM.

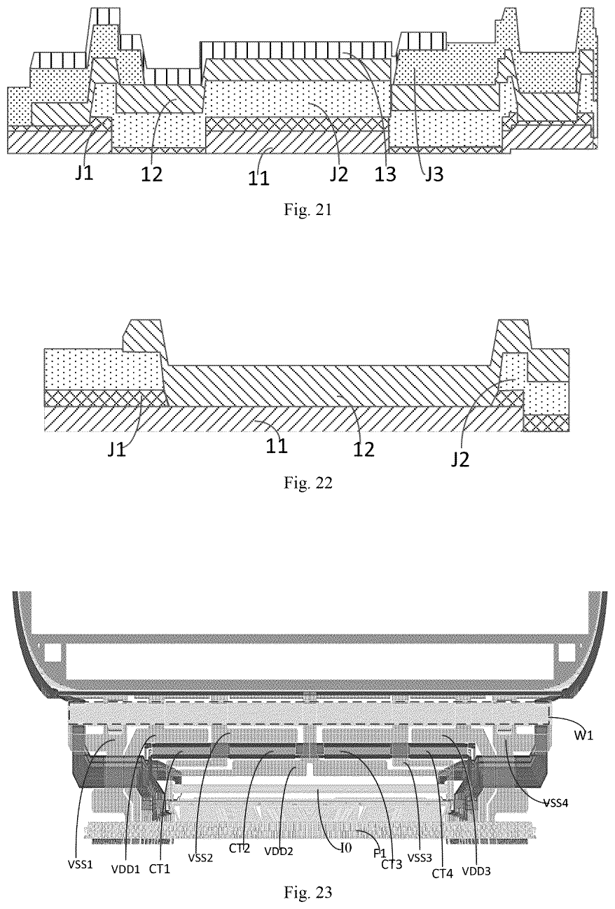

FIG. 21 is a sectional view of the first frame region in FIG. 17 along line C-C′, and FIG. 22 is a sectional view of the first frame region in FIG. 17 along line D-D′.

In FIGS. 21, 11 represents the first source/drain metal layer, 12 represents the second source/drain metal layer, JI represents a first insulation layer, J2 represents a second insulation layer, 13 represents an anode layer, and J3 represents a third insulation layer.

In FIG. 22, I1 represents the first source/drain metal layer, 12 represents the second source/drain metal layer, J1 represents the first insulation layer, and J2 represents the second insulation layer.

In a possible embodiment of the present disclosure, the first insulation layer is a passivation layer, the second insulation layer is a first planarization layer, and the third insulation layer is a second planarization layer.

FIG. 23 is a schematic view showing the layout of the first frame region of the display substrate according to one embodiment of the present disclosure.

In FIG. 23, VSS1 represents a first one of the first voltage lines, VSS2 represents a second one of the first voltage lines, VSS3 represents a third one of the first voltage lines, VSS4 represents a fourth one of the first voltage lines, VDD1 represents a first one of the second voltage lines, VDD2 represents a second one of the second voltage lines, and VDD3 represents a third one of the second voltage lines.

In FIGS. 23, I0 represents a driving integrated circuit, and F1 represents a flexible printed circuit. VSS1, VSS2, VSS3, VSS4, VDD1, VDD2 and VDD3 are electrically coupled to different ports of the flexible printed circuit F1. The flexible printed circuit F1 is configured to provide the first voltage signal to VSS1, VSS2, VSS3 and VSS4, and provide the second voltage signal to VDD1, VDD2 and VDD3. CT1 represents a first cell test region, CT2 represents a second cell test region, CT3 represents a third cell test region, and CT4 represents a fourth cell test region.

In at least one embodiment of the present disclosure, as shown in FIG. 23, the second voltage line is added at a central position of the display substrate, and the first voltage line is newly added at either of two sides of the second voltage line. The added voltage lines are electrically coupled to different ports of the flexible printed circuit F1, and a scheme where the first voltage line above the bending region W1 is lapped onto the second voltage line is the same as that in FIG. 1A. In the embodiments of the present disclosure, it is able to shunt the first voltage signal and the second voltage signal simultaneously, and reduce a load of the first voltage line and a load of the second voltage line, thereby to improve the brightness uniformity.

FIG. 24 is a schematic view showing the layout of a left half portion of the first frame region in FIG. 23.

FIG. 25 is a schematic view showing the layout of the first source/drain metal layer in FIG. 24, FIG. 26 is a schematic view showing the layout of the second source/drain metal layer in FIG. 24, FIG. 27 is a schematic view showing the layout of a first gate metal layer in FIG. 24, FIG. 28 is a schematic view showing the layout of a second gate metal layer in FIG. 24, and FIG. 29 is a schematic view showing the layout of the anode layer in FIG. 24.

The present disclosure further provides in some embodiments a display panel including the above-mentioned display substrate.

The above are the preferred embodiments of the present disclosure. It should be noted that, a person skilled in the art may further make improvements and modifications without departing from the principle of the present disclosure, and these improvements and modifications shall also be considered as the scope of the present disclosure.

1. A display substrate, comprising a display region and a first frame region, wherein the display substrate comprises:
a base substrate;
a plurality of first voltage lines and a plurality of second voltage lines arranged on the base substrate and in the first frame region, the second voltage line being arranged between two adjacent first voltage lines in the first direction, the plurality of first voltage lines being electrically coupled to each other, the plurality of second voltage lines being electrically coupled to each other; and
a circuit board arranged on the base substrate and in the first frame region, the circuit board being arranged at a side of the first voltage line and the second voltage line away from the display region, and the circuit board being electrically coupled to the plurality of first voltage lines and configured to provide a first voltage signal to the first voltage line.

2. The display substrate according to claim 1, wherein the display substrate comprises at least three second voltage lines arranged in the first frame region, the first voltage line is arranged between the adjacent second voltage lines in the first direction, and the circuit board is electrically coupled to the at least three second voltage lines and configured to provide a second voltage signal to the second voltage line.

3. The display substrate according to claim 1, wherein the display substrate comprises at least three first voltage lines arranged in the first frame region; and
the at least three first voltage lines and the plurality of second voltage lines are arranged sequentially in the first direction.

4. The display substrate according to claim 3, wherein the display substrate comprises a first one of the first voltage lines, a first one of the second voltage lines, a second one of the first voltage lines, a second one of the second voltage lines and a third one of the first voltage lines arranged sequentially in the first frame region in the first direction; or
the display substrate comprises a first one of the first voltage lines, a first one of the second voltage lines, a second one of the first voltage lines, a second one of the second voltage lines, a third one of the first voltage lines, a third one of the second voltage lines and a fourth one of the first voltage lines arranged sequentially in the first frame region in the first direction.

5. The display substrate according to claim 1, wherein the first frame region comprises a bending region and a first region, the first region is arranged at a side of the bending region close to the display region, the display substrate further comprises a first metal layer arranged on the base substrate, the display substrate further comprises a second voltage communication line formed at the first metal layer, the second voltage communication line extends in the first direction, the second voltage communication line is arranged in the first region, and the plurality of second voltage lines is coupled to the second voltage communication line so that the plurality of second voltage lines is electrically coupled to each other.

6. The display substrate according to claim 5, further comprising a first side region and a second side region, wherein the first region comprises an are-like region, the first side region is arranged at a first side of the display region, the second side region is arranged at a second side of the display region, the first side and the second side are opposite sides, the arc-like region is a region comprised in the first region close to the first side region or the second side region, and a portion of one of the first voltage lines of the display substrate is arranged in the arc-like region.

7. The display substrate according to claim 6, further comprising a second metal layer arranged at a side of the first metal layer away from the base substrate,
wherein the display substrate further comprises a plurality of second voltage connection lines arranged in the arc-like region and extending in a second direction, the second voltage connection line is formed at the second metal layer, the first direction intersects the second direction, and the second voltage connection line is electrically coupled to the second voltage communication line via a through-hole.

8. The display substrate according to claim 7, further comprising a first voltage connection line extending in the second direction, and a plurality of first conductive connection members electrically coupled to ends of the first voltage connection lines away from the display region, wherein the first voltage connection line and the first conductive connection member are arranged in the arc-like region, the first direction intersects the second direction, and the first voltage connection line and the first conductive connection member are formed at the second metal layer,
wherein the display substrate further comprises a first voltage line portion arranged in the arc-like region, the first voltage line portion is comprised in the first voltage line, the first voltage line portion extends in the first direction and is formed at the first metal layer, an orthogonal projection of the first voltage line portion onto the base substrate at least partially overlaps with an orthogonal projection of the first conductive connection portion onto the base substrate, and the first conductive connection member is electrically coupled to the first voltage line portion via a through-hole.

9. The display substrate according to claim 8, wherein the second voltage connection lines and the first conductive connection members are arranged alternately in the first direction.

10. The display substrate according to claim 6, further comprising a plurality of first connection lines and a plurality of second connection lines arranged in the arc-like region, the first connection line and the second connection line extend in a second direction, and the first connection line and the second connection line are formed at a second metal layer;
the second connection line is arranged at a side of the first connection line away from the display region, at least two of the first connection lines are electrically coupled to one of the second connection lines, and the first direction intersects the second direction; and
the second connection line is electrically coupled to the second voltage communication line via a through-hole.

11. The display substrate according to claim 10, further comprising a plurality of first voltage connection lines arranged in the arc-like region and extending in the second direction, and a plurality of second conductive connection members electrically coupled to ends of the first voltage connection lines away from the display region, wherein the first direction intersects the second direction, and the first voltage connection line and the second conductive connection member are formed at the second metal layer;
the display substrate further comprises a first voltage line portion arranged in the arc-like region, the first voltage line portion is comprised in the first voltage line, the first voltage line portion extends in the first direction, the first voltage line portion is formed at the first metal layer, and an orthogonal projection of the first voltage line portion onto the base substrate at least partially overlaps with an orthogonal projection of the second conductive connection member onto the base substrate; and
the second conductive connection member is electrically coupled to the first voltage line portion via a through-hole.

12. The display substrate according to claim 11, wherein the second connection lines and the second conductive connection members are arranged alternately in the first direction; and
an area of the orthogonal projection of the second conductive connection member onto the base substrate is greater than or equal to 500 μm² and smaller than or equal to 1200 μm².

13. The display substrate according to claim 8, wherein an orthogonal projection of the second voltage communication line onto the base substrate is arranged at a side of the orthogonal projection of the first voltage line portion onto the base substrate away from the display region.

14. The display substrate according to claim 8, wherein in the arc-like region, the first voltage line further comprises a second voltage line portion formed at the second metal layer, a third voltage line portion formed at the first metal layer, and a fourth voltage line portion formed at a conductive layer;
the second voltage line portion is electrically coupled to the first voltage line portion via a through-hole, and the orthogonal projection of the first voltage line portion onto the base substrate at least partially overlaps with an orthogonal projection of the second voltage line portion onto the base substrate;
an orthogonal projection of the third voltage line portion onto the base substrate is arranged at a side of the orthogonal projection of the first voltage line portion onto the base substrate away from the display region; and
an orthogonal projection of the fourth voltage line portion onto the base substrate at least partially overlaps with the orthogonal projection of the second voltage line portion onto the base substrate, the orthogonal projection of the fourth voltage line portion onto the base substrate at least partially overlaps with the orthogonal projection of the third voltage line portion onto the base substrate, and the fourth voltage line portion is electrically coupled to the second voltage line portion and the third voltage line portion so that the second voltage line portion is electrically coupled to the third voltage line portion.

15. The display substrate according to claim 6, wherein a region comprised in the first region other than the arc-like region is a middle region, and in the middle region, the first voltage line comprises a fifth voltage line portion, a sixth voltage line portion, a seventh voltage line portion, an eighth voltage line portion and a ninth voltage line portion;
the fifth voltage line portion, the sixth voltage line portion, the seventh voltage line portion, the eighth voltage line portion and the ninth voltage line portion extend in the first direction;
the fifth voltage line portion and the sixth voltage line portion are formed at the first metal layer, the seventh voltage line portion and the eighth voltage line portion are formed at a second metal layer, and the ninth voltage line portion is formed at a conductive layer;
an orthogonal projection of the seventh voltage line portion onto the base substrate and an orthogonal projection of the ninth voltage line portion onto the base substrate at least partially overlap with an orthogonal projection of the second voltage communication line onto the base substrate; the ninth voltage line portion, the seventh voltage line portion, the fifth voltage line portion and the sixth voltage line portion are electrically coupled to each other; and
the seventh voltage line portion is electrically coupled to the eighth voltage line portion.

16. The display substrate according to claim 15, wherein a length of the second voltage communication line in a second direction is greater than or equal to 20 μm and smaller than or equal to 120 μm.

17. The display substrate according to claim 15, wherein the seventh voltage line portion is electrically coupled to the eighth voltage line portion via a through-hole, the seventh voltage line portion is in direct contact with the eighth voltage line portion at the through-hole, and an area of the seventh voltage line portion in direct contact with the eighth voltage line portion is greater than or equal to 40000 μm² and smaller than or equal to 100000 μm².

18. A display panel, comprising the display substrate according to claim 1.

19. The display substrate according to claim 11, wherein an orthogonal projection of the second voltage communication line onto the base substrate is arranged at a side of the orthogonal projection of the first voltage line portion onto the base substrate away from the display region.

20. The display substrate according to claim 11, wherein in the arc-like region, the first voltage line further comprises a second voltage line portion formed at the second metal layer, a third voltage line portion formed at the first metal layer, and a fourth voltage line portion formed at a conductive layer;
the second voltage line portion is electrically coupled to the first voltage line portion via a through-hole, and the orthogonal projection of the first voltage line portion onto the base substrate at least partially overlaps with an orthogonal projection of the second voltage line portion onto the base substrate;
an orthogonal projection of the third voltage line portion onto the base substrate is arranged at a side of the orthogonal projection of the first voltage line portion onto the base substrate away from the display region; and
an orthogonal projection of the fourth voltage line portion onto the base substrate at least partially overlaps with the orthogonal projection of the second voltage line portion onto the base substrate, the orthogonal projection of the fourth voltage line portion onto the base substrate at least partially overlaps with the orthogonal projection of the third voltage line portion onto the base substrate, and the fourth voltage line portion is electrically coupled to the second voltage line portion and the third voltage line portion so that the second voltage line portion is electrically coupled to the third voltage line portion.
